(19) United States
(12) Patent Application Publication
(10) Pub. No.: US 2023/0079401 A1
(43) Pub. Date: Mar. 16, 2023

(54) SECONDARY BATTERY CONTROL DEVICE, BATTERY PACK, AND SECONDARY BATTERY CONTROL METHOD

(71) Applicant: TDK CORPORATION, Tokyo (JP)

(72) Inventors: Ken NAKAMURA, Tokyo (JP); Eishi ENDO, Tokyo (JP)

(73) Assignee: TDK CORPORATION, Tokyo (JP)

(21) Appl. No.: 17/799,473

(22) PCT Filed: Mar. 17, 2020
(86) PCT No.: PCT/JP2020/011669

§ 371 Date: Aug. 12, 2022

(51) Int. Cl. H01M 10/42; H01M 10/0525; H01M 4/36; H01M 4/525; H01M 4/505; G01R 31/392; G01R 31/367; G01R 31/378

(52) U.S. Cl. CPC H01M 10/425; H01M 10/0525; H01M 4/364; H01M 4/525; H01M 4/505; H01M 10/4207; G01R 31/392; G01R 31/367; G01R 31/378; H01M 2004/028

(57) ABSTRACT

A secondary battery control device, on a Q-dQ/dV curve, when a capacity between two characteristic points or two points mathematically equivalent thereto is represented by α, a dQ/dV value at any extreme point of a plurality of extreme points plotted on the Q-dQ/dV curve or a point mathematically equivalent thereto is represented by β, a product of the α and the β is represented by X, and constants obtained in advance from a relationship between the X in a correction sample and a deterioration degree of the correction sample are represented by A and B, a deterioration degree SOH of the secondary battery is corrected to SOH=AX+B . . . (1). A battery pack including this secondary battery control device is highly safe, contributes to the stable supply of energy and contributes to sustainable development goals.

### TECHNICAL FIELD

The present invention relates to a secondary battery control device, a battery pack and a secondary battery control method.

### BACKGROUND ART

As the index of the state of a secondary battery, the state of charge (SOC) or the state of health (SOH) is known. The SOC is an index indicating the remaining capacity of a secondary battery, and the SOH is an index indicating the deterioration state of a battery. The SOC is the ratio of the remaining capacity relative to the full charge capacity. The SOH is the ratio of the capacity from fully charged to fully discharged upon deterioration relative to the initial capacity from fully charged to fully discharged.

For example, Patent Document 1 describes a method for estimating the capacity reduction rate (corresponding to the SOH) at the time of charging a secondary battery from the voltage value at the maximum point of a V-dQ/dV curve that is obtained from dQ/dV, which is the ratio of the amount of change in the capacity to the amount of change in the voltage, and the voltage V of the secondary battery.

For example, Patent Document 2 describes a method in which, at the time of discharging a secondary battery, dQ/dV is obtained, and the SOH is obtained from the maximum value of the amount of change in dQ/dV relative to the voltage.

### CITATION LIST

### Patent Literature

### [Patent Document 1]

Japanese Patent Laid-Open No. 2013-19709

### [Patent Document 2]

Japanese Patent Laid-Open No. 2016-9659

### SUMMARY OF INVENTION

### Technical Problem

When the charge and discharge cycle of a secondary battery is repeated, there is a case where an estimated SOH value deviates from the actual SOH value. In the methods described in Patent Documents 1 and 2, it is not possible to sufficiently decrease the error between an actual SOH value and an estimated SOH value.

The present disclosure has been made in consideration of the above-described problem, and an objective of the present invention is to provide a secondary battery control device, a battery pack and a secondary battery control method capable of correcting the deterioration states of secondary batteries to appropriate values.

### Solution to Problem

In order to solve the above-described problem, the following means is provided.

(1) A secondary battery control device according to a first aspect, in which, on a Q-dQ/dV curve where dQ/dV that is a ratio of an amount of change in a capacity of a secondary battery to an amount of change in a voltage is indicated along a vertical axis and the capacity of the secondary battery is indicated along a horizontal axis, when a capacity between two characteristic points or two points mathematically equivalent thereto is represented by α, a dQ/dV value at any extreme point of a plurality of extreme points plotted on the Q-dQ/dV curve or a point mathematically equivalent thereto is represented by β, a product of the α and the β is represented by X, and constants obtained in advance from a relationship between the X in a correction sample and a deterioration degree of the correction sample are represented by A and B, a deterioration degree SOH of the secondary battery is corrected to SOH=AX+B . . . (1).

(2) In a secondary battery control method according to the above-described aspect, both of the two characteristic points may be any of the plurality of extreme points.

(3) In a secondary battery control method according to the above-described aspect, the two characteristic points may be two points sandwiching any of the plurality of extreme points.

(4) In the secondary battery control method according to the above-described aspect, the extreme point sandwiched by the two characteristic points may be a maximum point plotted in a voltage range of 3.6 V or higher and 3.8 V or lower on a V-dQ/dV curve where dQ/dV that is a ratio of an amount of change in a capacity of a secondary battery to an amount of change in a voltage is indicated along a vertical axis and the voltage of the secondary battery is indicated along a horizontal axis.

(5) The secondary battery control method according to the above-described aspect may have dQ/dV calculation means for calculating the dQ/dV, capacity-between-two-point calculation means for selecting the two characteristic points on the Q-dQ/dV curve and obtaining the capacity between the two characteristic points, intensity calculation means for selecting any extreme point of the plurality of extreme points on the Q-dQ/dV curve and obtaining a dQ/dV value at the extreme point, a calculation means for obtaining a product of the capacity between the two characteristic points and the dQ/dV value, and correction means for correcting the deterioration degree of the secondary battery to a correction value based on a value obtained with the calculation means.

(6) A battery pack according to a second aspect includes a secondary battery and the secondary battery control device according to the above-described aspect.

(7) In the battery pack according to the above-described aspect, the secondary battery may contain a lithium nickel cobalt manganese composite oxide (NCM) and a lithium manganese oxide (LMO) in a positive electrode as active materials.

(8) A secondary battery control method according to a third aspect, in which, on a Q-dQ/dV curve where dQ/dV that is a ratio of an amount of change in a capacity of a secondary battery to an amount of change in a voltage is indicated along a vertical axis and the capacity of the secondary battery is indicated along a horizontal axis, when a capacity between two characteristic points or two points mathematically equivalent thereto is represented by α, a dQ/dV value at any extreme point of a plurality of extreme points plotted on the Q-dQ/dV curve or a point mathematically equivalent thereto is represented by β, a product of the α and the β is represented by X, and constants obtained in advance from a relationship between the X in a correction sample and a deterioration degree of the correction sample are represented by A and B, a deterioration degree SOH of the secondary battery is corrected to SOH=AX+B . . . (1).

### Advantageous Effects of Invention

The secondary battery control device, the battery pack and the secondary battery control method according to the above-described aspects are capable of correcting the deterioration states of secondary batteries to appropriate values.

In addition, the secondary battery control device, the battery pack and the secondary battery control method according to the above-described aspects contribute to the stably supply of energy by enhancing the safety of secondary batteries and contribute to sustainable development goals.

### BRIEF DESCRIPTION OF DRAWINGS

FIG. 1 is a block diagram of a battery pack according to a first embodiment.

FIG. 2 is an example of a Q-dQ/dV curve and a Q-V curve of a secondary battery according to the first embodiment.

FIG. 3 is a view showing a relationship between a deterioration degree of a correction sample and a product of a capacity between two characteristic points and a dQ/dV value at a specific extreme point.

FIG. 4 is a cross-sectional view of the secondary battery according to the first embodiment.

FIG. 5 is a view showing relationships between an index value of deterioration and an SOH of a secondary battery.

FIG. 6 is an example of a Q-dQ/dV curve and a Q-V curve of a secondary battery according to a second embodiment.

FIG. 7 is an example of a V-dQ/dV curve of the secondary battery according to the second embodiment.

FIG. 8 is a view showing a relationship between an index value of deterioration and an SOH of a secondary battery.

### DESCRIPTION OF EMBODIMENTS

Hereinafter, embodiments will be described in detail with appropriate reference to the drawings. In the drawing to be used in the following description, there is a case where a characteristic part is shown in an enlarged manner for convenience in order to facilitate the understanding of the characteristics, and the dimensional ratio and the like between individual configuration elements are different from actual ones in some cases. Materials, dimensions, and the like to be exemplified in the following description are simply examples, and the present invention is not limited thereto and can be appropriately modified and carried out within the scope of the gist of the present invention.

### First Embodiment

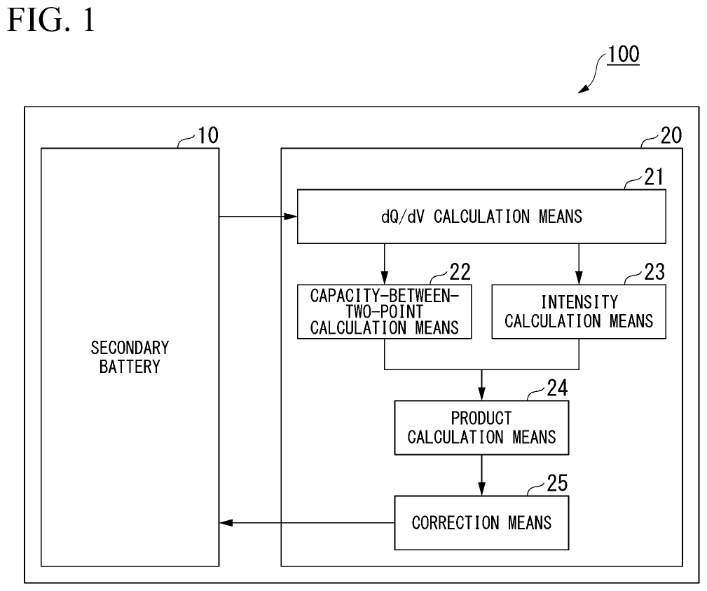

FIG. 1 is a block diagram of a battery pack 100 according to a first embodiment. The battery pack 100 includes a secondary battery 10 and a control device 20. Signals are communicated between the secondary battery 10 and the control device 20. Signals communication may be wired or wireless.

The secondary battery 10 is, for example, a lithium secondary battery. The specific configuration of the secondary battery 10 will be described below. The secondary battery 10 deteriorates from use. An index of the deterioration of the secondary battery 10 is the SOH. The SOH is represented by “the capacity (Ah) from fully charged to fully discharged upon deterioration/the initial capacity (Ah) from fully charged to fully discharged x 100”. Appropriate evaluation of the SOH leads to extension of battery lives.

The control device 20 is a control device (controller) that controls the secondary battery 10. The control device 20 is, for example, a microcomputer.

The control device 20 has a control program that corrects the deterioration degree of the secondary battery 10 to SOH=AX+B . . . (1). Hereinafter, the control device 20 will be described using a specific example of the control device 20.

The control device 20 has, for example, dQ/dV calculation means 21, capacity-between-two-point calculation means 22, intensity calculation means 23, product calculation means 24 and correction means 25. The dQ/dV calculation means 21, the capacity-between-two-point calculation means 22, the intensity calculation means 23, the product calculation means 24 and the correction means 25 are, for example, programs stored in the control device 20.

The dQ/dV calculation means 21 monitors the voltage and the capacity of the secondary battery 10. The dQ/dV calculation means 21 calculates dQ/dV from the amount of change in the voltage per unit time and the amount of change in the capacity, dQ/dV may be calculated upon charging or may be calculated upon discharging. dQ/dV is preferably calculated upon charging.

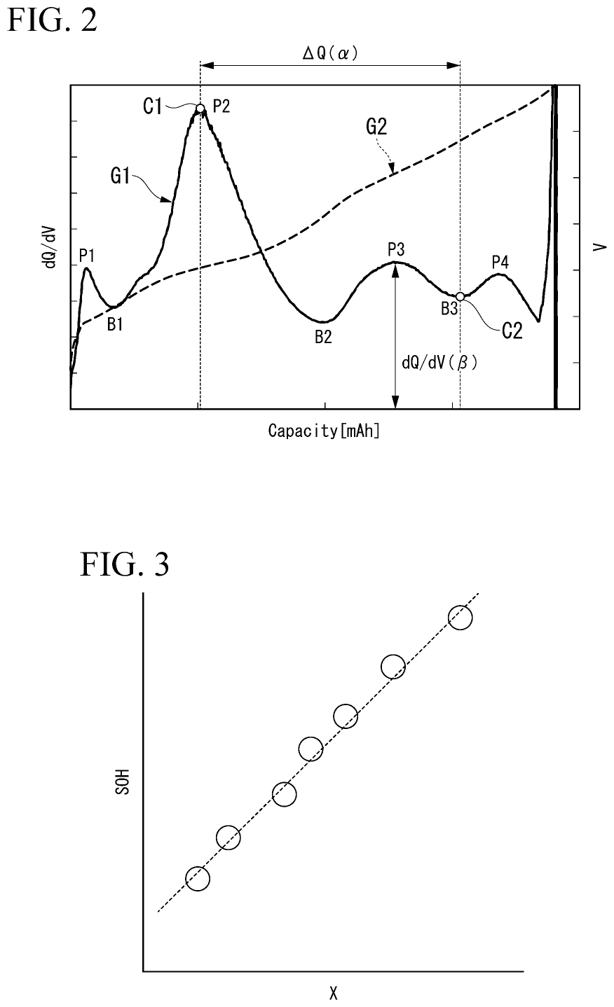

The dQ/dV calculation means 21 draws a Q-dQ/dV curve based on the calculated dQ/dV. FIG. 2 is an example of the Q-dQ/dV curve and a Q-V curve. A graph G1 shown in FIG. 2 is the Q-dQ/dV curve. For the Q-dQ/dV curve, the horizontal axis indicates the capacity of the secondary battery, and the vertical axis indicates dQ/dV. A graph G2 shown in FIG. 2 is the Q-V curve. For the Q-V curve, the horizontal axis indicates the capacity of the secondary battery, and the vertical axis indicates the voltage of the secondary battery. The Q-dQ/dV curve is a Q-V curve measured by a charge and discharge test and differentiated with respect to the voltage.

As shown in FIG. 2, the Q-dQ/dV curve has a plurality of extreme points. The extreme points include the maximum points and the minimum points. In FIG. 2, P1, P2, P3 and P4 are the maximum points, and B1, B2 and B3 are the minimum points. The maximum points on the Q-dQ/dV curve correspond to parts where the voltage is flat on a charge and discharge curve (Q-V curve) where the horizontal axis indicates the capacity and the vertical axis indicates the voltage. That is, the maximum points correspond to parts where a battery reaction of a predetermined stage occurs. The minimum points on the Q-dQ/dV curve correspond to parts where the voltage significantly varies in the charge and discharge curve (Q-V curve). That is, the minimum points correspond to points where a battery reaction of a predetermined stage begins or ends.

The data of the Q-dQ/dV curve obtained with the dQ/dV calculation means 21 is sent to the capacity-between-two-point calculation means 22 and the intensity calculation means 23, respectively.

The capacity-between-two-point calculation means 22 obtains a capacity ΔQ between two characteristic points C1 and C2. The capacity ΔQ is an example of an index α. When the coordinate of the characteristic point C1 is represented by (X1, Y1) and the coordinate of the characteristic point C2 is represented by (X2, Y2), the capacity ΔQ is |X2−X1|.

The two characteristic points C1 and C2 are selected arbitrarily. The two characteristic points C1 and C2 are preferably specific points on the Q-dQ/dV curve. The Q-dQ/dV curve is drawn in, for example, a charging process of the secondary battery. Therefore, when the two characteristic points C1 and C2 are not specific points on the Q-dQ/dV curve, since it is difficult to mechanically determine whether or not the capacity reaches the characteristic points C1 and C2.

For example, as the two characteristic points C1 and C2, any of the plurality of extreme points are selected, respectively. The extreme point may be the maximum point or the minimum point. The capacity between the two characteristic points C1 and C2 may be the capacity between peaks, the capacity between bottoms or the capacity between a peak and a bottom on the Q-dQ/dV curve.

For example, in FIG. 2, the maximum point P2 is regarded as the characteristic point C1, and the minimum point B3 is regarded as the characteristic point C2. The maximum point P2 is an extreme point (maximum point) of a voltage stable region appearing second from the fully-discharged state in an initial charge and discharge test of the secondary battery. The minimum point B3 is an extreme point (minimum point) of a voltage fluctuation region appearing third from the fully-discharged state in the initial charge and discharge test of the secondary battery. Here, the expression “initial” means 10 or less charge and discharge cycles. The maximum point P2 is an extreme point of a voltage stable region based on, for example, the coexisting state of a stage 2L and a stage 2 in a stage structure of graphite in a negative electrode. The minimum point B3 is a minimum point appearing when a single-phase reaction of a hexagonal crystal of a manganese oxide contained in a positive electrode active material of the secondary battery 10 is completed.

The intensity calculation means 23 selects any extreme point of the plurality of extreme points on the Q-dQ/dV curve and obtains a dQ/dV value at the extreme point. The dQ/dV value at the selected extreme point is an example of the index β. When the coordinate of the selected extreme point is represented by (X3, Y3), the index β is Y3.

The extreme point is arbitrarily selected and may be any of the maximum points P1, P2, P3 and P4 or any of the minimum points B1, B2 and B3. The intensity calculation means 23 selects the extreme point with no relation to the extreme points selected as the characteristic points C1 and C2 in the capacity-between-two-point calculation means 22. When the minimum point B1. B2 or B3 is used as the extreme point, the determination coefficient R² of the relational formula (1) showing the deterioration degree of the secondary battery 10 becomes large, and the error between the actual SOH value and an estimated SOH value becomes small. When the minimum point B1 is used as the extreme point, the determination coefficient R² of the relational formula (1) showing the deterioration degree of the secondary battery 10 becomes particularly large. In addition, when the maximum point P2 or P3 or the minimum point B2 or B3 is used as the extreme point, it is possible to increase the correction frequency, and it is possible to decrease the error between the actual SOH value and an estimated SOH value. This is because, at the maximum points P2 and P3 and the minimum points B2 and B3, the passing frequency is large in the ordinary operation aspect of the battery.

For example, in FIG. 2, the maximum point P3 is selected, and the dQ/dV value at the maximum point P3 is calculated as the index β. The maximum point P3 is an extreme point (maximum point) of a voltage stable region appearing third from the fully-discharged state in an initial charge and discharge test of the secondary battery. The maximum point P3 is, for example, an extreme point of a voltage stable region based on a single-phase reaction of a hexagonal crystal of a manganese oxide.

The capacity ΔQ obtained with the capacity-between-two-point calculation means 22 and the dQ/dV value obtained with the intensity calculation means 23 are each sent to the product calculation means 24. The product calculation means 24 calculates a product X of the capacity ΔQ between the two characteristic points C1 and C2 and the dQ/dV value. The product X is, for example, a product of the capacity ΔQ and the dQ/dV value.

The correction means 25 estimates the SOH of the secondary battery 10 based on the product X sent from the product calculation means 24. The correction means corrects the SOH of the secondary battery 10 using the estimated SOH as a correction value.

The correction value satisfies the following formula (1).

SOH=AX+B (1)

In the formula (1), the SOH is an estimated deterioration degree of a secondary battery and is a correction value. In the formula (1), X is the product calculated with the product calculation means 24. In the formula (1). A and B are constants.

The constants of A and B are obtained in advance from the relationship between the product X in a correction sample and the deterioration degree of the correction sample. The constants of A and B vary with the combination of the extreme points that serve as the characteristic points C1 and C2 and the extreme point used for the calculation of the dQ/dV value. The constants of A and B are obtained in advance with the correction sample and stored in advance in the correction means 25.

Here, a method for obtaining the constants of A and B will be described. First, a correction sample is prepared. The correction sample is produced using the same material to have the same capacity as the secondary battery 10 that is actually used. The deterioration behaviors of the correction sample produced using the same material to have the same capacity are similar to the deterioration behaviors of the secondary battery 10 that is actually used.

Next, a charge and discharge test of the correction sample is carried out to obtain a Q-dQ/dV curve. The correction sample deteriorates as the charge and discharge cycle is repeated, and the form of the Q-dQ/dV curve changes. When the correction sample deteriorates, for example, the position of the extreme point in the vertical axis (dQ/dV) lowers, and the position of the extreme point in the horizontal axis (Q) shifts. The shifting behaviors of the extreme point on the Q-dQ/dV curve in the vertical axis (dQ/dV) direction and the horizontal axis (V) direction due to the deterioration of the correction sample substantially coincide with the shifting behaviors of the extreme point due to the deterioration of the secondary battery 10.

Next, two characteristic points are selected on the Q-dQ/dV curve of the correction sample, and the capacity between these characteristic points is obtained. The two characteristic points that are selected in the correction sample are the same as two characteristic points that are selected in the secondary battery 10 that is actually used. In other words, in the secondary battery 10 that is actually used, the two characteristic point selected in the correction sample are selected as two characteristic points. For example, two extreme points are selected as the two characteristic points.

In addition, one extreme point of the plurality of extreme points on the Q-dQ/dV curve of the correction sample is selected, and a dQ/dV value at this extreme point is obtained. One extreme point that is selected in the correction sample is the same as the extreme point that is used at the time of obtaining the dQ/dV value in the secondary battery 10 that is actually used. In other words, in the secondary battery 10 that is actually used, the extreme point selected in the correction sample is selected as the extreme point that is used at the time of obtaining the dQ/dV value.

In the correction sample, the capacity between two characteristic points and the dQ/dV value at a specific extreme point are obtained each time the charge and discharge cycle is carried out a predetermined number of times. In addition, each time the capacity between two characteristic points and the dQ/dV value at a specific extreme point are obtained, the product thereof is calculated. In addition, the deterioration degrees (SOH) of the correction sample at points in time when these products are calculated are obtained. The deterioration degree (SOH) of the correction sample can be obtained by dividing the capacity (Ah) from fully charged to fully discharged when the cycle has been carried out the above-described number of times by the initial capacity (Ah) from fully charged to fully discharged. For the correction sample, unlike the actual operation aspect of the secondary battery 10, there is no case where the correction sample is discharged in the middle of being charged or charged in the middle of being discharged, and thus the SOH can be obtained as an actual measurement value.

FIG. 3 shows the relationship between the deterioration degree of the correction sample and the product of the capacity between the two characteristic points and the dQ/dV value at a specific extreme point. As shown in FIG. 3, there is a linear correlation between the deterioration degree of the correction sample and the product of the capacity between the two characteristic points and the dQ/dV value at a specific extreme point.

Next, a regression line is drawn on the plot of the correction sample shown in FIG. 3. The slope of the regression line is the constant A, and the intercept of the regression line is the constant B. As the determination coefficient R² of the regression line becomes larger, the linear correlation of the regression line becomes stronger, and the estimation accuracy of the SOH becomes higher.

The correction means 25 sends the obtained correction value to the secondary battery 10. The SOH value of the secondary battery 10 is substituted by the correction value. The SOH value is substituted by the correction value, for example, after the capacity of the secondary battery has passed all of the selected minimum points during charging. The SOH value is substituted by the correction value, for example, each time the capacity of the secondary battery passes all of the selected extreme points during charging. The correction may be carried out at a point in time when the correction value has been obtained. In addition, the correction may be carried out by, after the correction value is obtained, adding the difference between the existing value (the value before correction) at a point in time when the correction value has been obtained and the correction value to the existing value at a point in time when the correction is carried out. In addition, the correction may be carried out by gradually correcting the value while the correction value is acquired and then the correction is completed such that a value corresponding to the difference between the existing value at a point in time when the correction value has been obtained and the correction value can be added to the existing value upon completion of the correction.

When the SOH is substituted by the correction value, for example, the continuously changing SOH value changes discontinuously. From the fact that the read SOH value has discontinuously changed, it is possible to estimate that correction has been carried out. In addition, in a case where the correction value at a point in time when the SOH has been corrected satisfies the relational formula (1), it is possible to estimate that a secondary battery control method according to the first embodiment has been carried out.

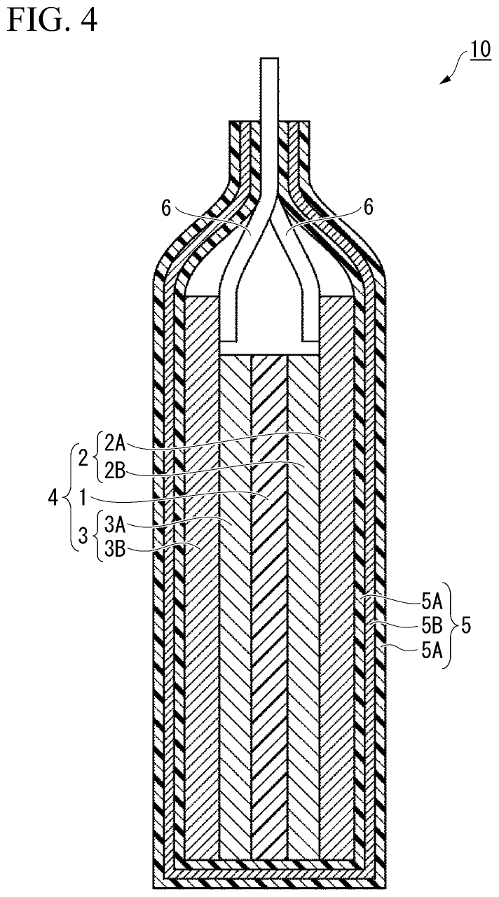

FIG. 4 is a schematic view of the secondary battery according to the first embodiment. The secondary battery 10 includes, for example, a power generation element 4, an exterior body 5 and an electrolytic solution (not shown). The exterior body 5 coats the circumference of the power generation element 4. The exterior body 5 is, for example, a metal-laminated film obtained by coating a metal foil 5A with polymer films (resin layers 5B) from both sides. The power generation element 4 is connected to the outside with a pair of terminals 6 connected to each other. The electrolytic solution is stored in the exterior body 5 and used to impregnate the power generation element 4.

The power generation element 4 includes a positive electrode 2, a negative electrode 3 and a separator 1. The separator 1 is sandwiched by the positive electrode 2 and the negative electrode 3. The separator 1 is, for example, a film having an electrically insulating porous structure. As the separator 1, a well-known separator can be used.

The positive electrode 2 has a positive electrode current collector 2A and a positive electrode active material layer 2B. The positive electrode active material layer 2B is formed on at least one surface of the positive electrode current collector 2A. The positive electrode active material layers 2B may be formed on both surfaces of the positive electrode current collector 2A. The positive electrode current collector 2A is, for example, a conductive sheet material. The positive electrode active material layer 2B has, for example, a positive electrode active material, a conductive auxiliary material and a binder.

The positive electrode active material reversibly progresses the occlusion and emission of lithium ions, the deintercalation and intercalation of lithium ions or the doping and de-doping of lithium ions and counter anions. The positive electrode active material is, for example, lithium cobalt oxide (LCO), lithium nickel cobalt manganese composite oxide (NCM), lithium nickel cobalt aluminum composite oxide (NCA), lithium manganese oxide (LMO) or lithium iron phosphate (LFP). The positive electrode active material layer 2B may contain a plurality of these positive electrode active materials. The positive electrode active material may be, for example, a positive electrode active material represented by LMO₂. M is any one transition metal element selected from the group consisting of Co, Ni, Al, Mn and Fe. The positive electrode active material is not limited thereto, and a well-known positive electrode active material can be used. As the conductive auxiliary material and the binder, well-known conductive auxiliary material and binder can be used.

The negative electrode 3 has a negative electrode current collector 3A and a negative electrode active material layer 3B. The negative electrode active material layer 3B is formed on at least one surface of the negative electrode current collector 3A. The negative electrode active material layers 3B may be formed on both surfaces of the negative electrode current collector 3A. The negative electrode current collector 3A is, for example, a conductive sheet material. The negative electrode active material layer 3B has, for example, a positive electrode active material, a conductive auxiliary material and a binder.

As the negative electrode active material, any negative electrode active material that can be used in well-known lithium-ion secondary batteries can be used as long as the negative electrode active material is a compound capable of occluding and emitting ions. The negative electrode active material is, for example, graphite. The negative electrode active material may be metallic lithium, a silicon compound or the like.

The electrolytic solution is enclosed in the exterior body 5 and used to impregnate the power generation element 4. As the electrolytic solution, a well-known electrolytic solution can be used.

The battery pack 100 according to the first embodiment is capable of correcting the SOH of the secondary battery 10 to an appropriate value with the control device 20.

The control device 20 according to the first embodiment corrects the SOH of the secondary battery 10 using the product of the capacity between two characteristic points on a Q-dQ/dV curve and a dQ/dV value at an extreme point. The capacity between two characteristic points contains information on a change of the Q-dQ/dV curve in the horizontal axis (Q) direction due to deterioration. The dQ/dV value at an extreme point contains information on a change of the Q-dQ/dV curve in the vertical axis (dQ/dV) direction due to deterioration. When a change in the form of the Q-dQ/dV curve due to deterioration is specified using values having information on shape changes in two different directions, it is possible to accurately grasp the deterioration state of the secondary battery 10.

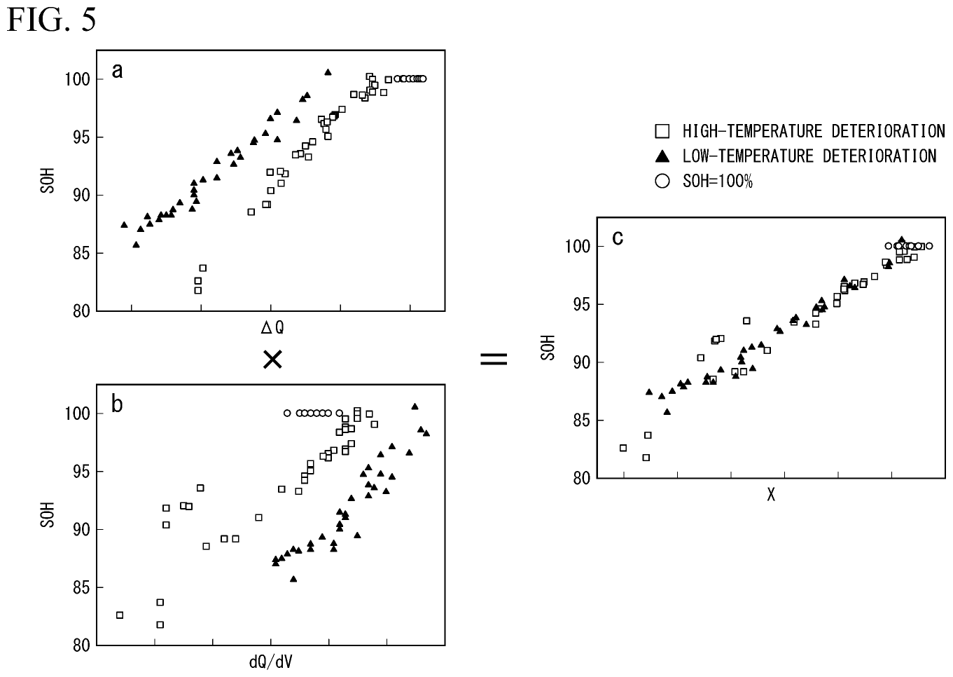

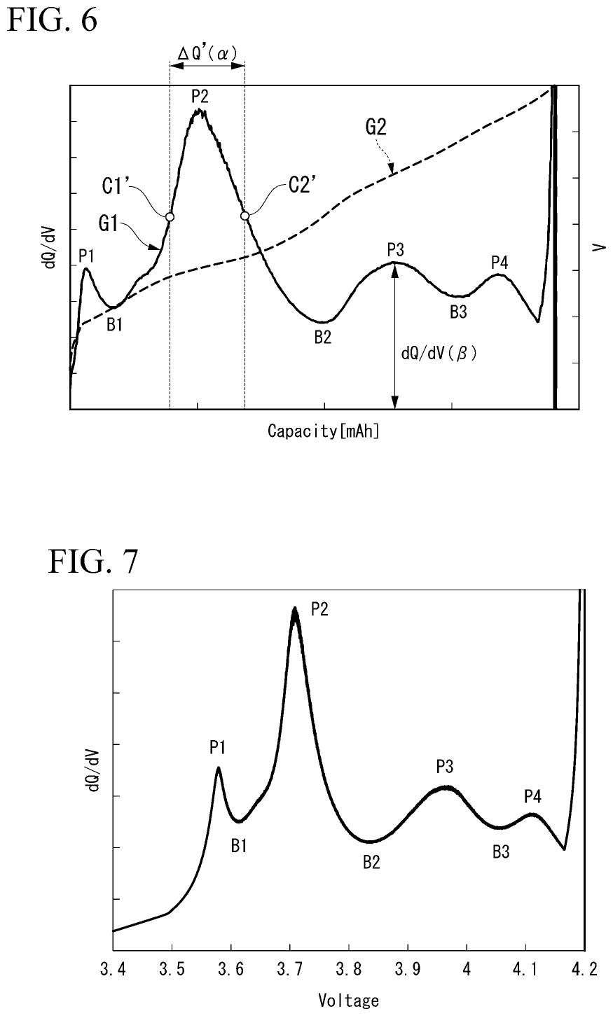

FIG. 5 is a view showing the relationships between an index value of deterioration and the SOH of the secondary battery 10. A graph a shown in FIG. 5 is a view in which only the capacity between two characteristic points (index α) is used as an index value of deterioration. For the graph a, the horizontal axis indicates the capacity, and the vertical axis indicates the SOH. The two characteristic points in the graph a are two extreme points and are the maximum point P4 and the minimum point B1. A graph b shown in FIG. 5 is a view in which only the dQ/dV value at an extreme point (index β) is used as an index value of deterioration. For the graph b, the horizontal axis indicates the dQ/dV value, and the vertical axis indicates the SOH. The extreme point in the graph b is the minimum point B1. A graph c shown in FIG. 5 is a view in which the product X of the capacity between two characteristic points (index α) and the dQ/dV value at an extreme point (index β) is used as an index value of deterioration. For the graph c, the horizontal axis indicates the product X of the capacity between two characteristic points and the dQ/dV value, and the vertical axis indicates the SOH.

The graph c shown in FIG. 5 is more linear than the graphs a and b. This is considered to be because, in the graph c shown in FIG. 5, the index value of deterioration contains information on a change of the Q-dQ/dV curve in the horizontal axis (Q) direction and information on a change thereof in the vertical axis (dQ/dV) direction. In the graph a shown in FIG. 5, the index value of deterioration only contains information on a change of the Q-dQ/dV curve in the horizontal axis (Q) direction, and, in the graph b shown in FIG. 5, the index value of deterioration only contains information on a change of the Q-dQ/dV curve in the vertical axis (dQ/dV) direction.

In addition, in the graph c shown in FIG. 5, the same regression line can be drawn by a low-temperature deterioration test in which the charge and discharge cycle is carried out at 0° C. and by a high-temperature deterioration test in which the charge and discharge cycle is carried out at 60° C. That is, when the product X of the capacity between two characteristic points (index α) and the dQ/dV value at an extreme point (index β) is used as the index value of deterioration, it is possible to accurately estimate the SOH of the secondary battery 10 even in a case where the secondary battery 10 has been used under a variety of temperature conditions.

Hitherto, the embodiment of the present invention has been described in detail with reference to the drawing, but each configuration in each embodiment, a combination thereof, and the like are examples, and the addition, omission, substitution, and other modification of the configuration are possible within the scope of the gist of the present invention.

For example, instead of the capacity between two characteristic points, capacities at two points mathematically equivalent to the two characteristic points may be used in the calculation of the product, and, instead of the dQ/dV value at an extreme point, a dQ/dV value at a point mathematically equivalent to the extreme point may be used in the calculation of the product. Here, the expression “point mathematically equivalent” means that two points are in an equivalent relationship by mathematic conversion. For example, the Q-dQ/dV curve is a Q-V curve differentiated by the voltage V. Therefore, each of the extreme points of dQ/dV is mathematically equivalent to inflection points on a normal Q-V curve. In addition, the Q-dQ/dV curve can also be rewritten as a V-dQ/dV curve by mathematical conversion.

For example, the correction value may also be calculated by selecting two inflection points at which the reciprocal of the slope on the Q-V curve becomes the maximum or the minimum and using the capacity between these two inflection points. In addition, the correction value may also be calculated by, for example, using the slope at an inflection point on the Q-V curve. In this case, the inflection point on the Q-V curve is used even in the case of deriving the constants A and B in the correction sample. In this case, only the index that is used for the calculation of correction is changed, and an estimated correction value (SOH) can be calculated by the same procedure as in a case where the product of the capacity between two characteristic points and the dQ/dV value is used.

### Second Embodiment

A battery pack according to a second embodiment is different from the battery pack according to the first embodiment in terms of how to select characteristic points in the capacity-between-two-point calculation means 22. The other configurations are the same as those of the battery pack according to the first embodiment, and the same configurations will not be described again.

The capacity-between-two-point calculation means 22 obtains a capacity ΔQ′ between two characteristic points C1′ and C2′. When the coordinate of the characteristic point C1′ is represented by (X1′, Y1′) and the coordinate of the characteristic point C2′ is represented by (X2′, Y2′), the capacity ΔQ′ is X2′-X1′. ΔQ′ is an example of the index α.

The two characteristic points C1′ and C2′ are two points sandwiching any of the plurality of extreme points. The two characteristic points C1′ and CT are positions obtained by, for example, dividing the difference between the dQ/dV values at two adjacent extreme points at a predetermined ratio and shifting the extreme point with a larger dQ/dV value in the vertical direction by the predetermined ratio based on the extreme point with a smaller dQ/dV value. The two characteristic points C1′ and C2′ are present, for example, at positions where a straight line that passes through the central point in the vertical axis direction between a specific extreme point and an extreme point adjacent to the specific extreme point on the high-capacity side and is parallel to the horizontal axis and the Q-dQ/dV curve intersect with each other. The width between the two characteristic points C1′ and CT is, for example, the half-value width of one extreme point.

The extreme point sandwiched by the two characteristic points C1′ and C2′ is a maximum point plotted in a voltage range of 3.6 V or higher and 3.8 V or lower on a V-dQ/dV curve where dQ/dV that is the ratio of the amount of change in the capacity of a secondary battery to the amount of change in a voltage is indicated along a vertical axis and the voltage of the secondary battery is indicated along a horizontal axis. FIG. 7 is a view obtained by converting the Q-dQ/dV curve to a V-dQ/dV curve. The maximum point P2 is a maximum point appearing in a voltage range of 3.6 V or higher and 3.8 V or lower. The maximum point P2 changes significantly due to deterioration, and, when the point is used as an index of deterioration, it is possible to accurately estimate the SOH of the secondary battery 10.

In the battery pack according to the second embodiment, the same effect as that of the battery pack 100 according to the first embodiment can be obtained.

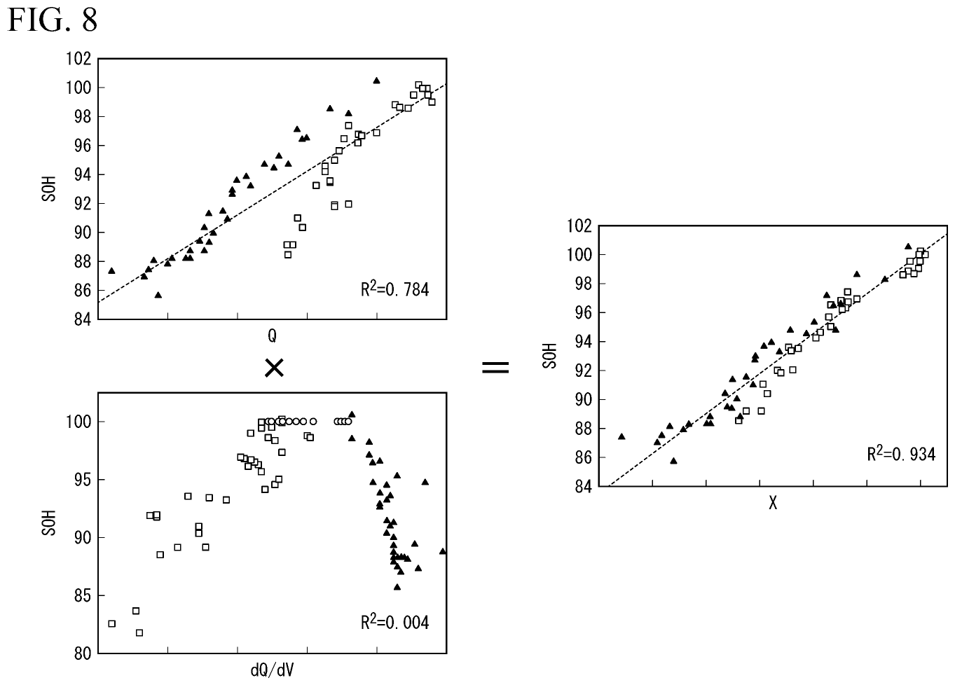

FIG. 8 is a view showing the relationships between an index value of deterioration and the SOH of the secondary battery 10. A graph a shown in FIG. 8 is a view in which only the capacity between two characteristic points (index α) is used as an index value of deterioration. The two characteristic points are points sandwiching the maximum point P2 and are two points at positions higher than the minimum point B2 by a third distance when the vertical distance between the maximum point P2 and the minimum point B2 is divided into three parts. For the graph a, the horizontal axis indicates the capacity, and the vertical axis indicates the SOH. A graph b shown in FIG. 8 is a view in which only the dQ/dV value at an extreme point (index β) is used as an index value of deterioration. For the graph b, the horizontal axis indicates the dQ/dV value, and the vertical axis indicates the SOH. A graph c shown in FIG. 8 is a view in which the product X of the capacity ΔQ′ between two characteristic points (index α) and the dQ/dV value at an extreme point (index β) is used as an index value of deterioration.

In contrast to the fact that the determination coefficient R² of the regression line is 0.784 in the graph a and the determination coefficient R² of the regression line is 0.004 in the graph b, the determination coefficient R² of the regression line is 0.934 in the graph c. That is, the graph c is more linear than the graphs a and b. This is considered to be because, in the graph c, similar to the graph shown in the first embodiment, the index value of deterioration contains information on a change of the Q-dQ/dV curve in the horizontal axis (Q) direction and information on a change thereof in the vertical axis (dQ/dV) direction.

In addition, in the graph c, the same regression line can be drawn by a low-temperature deterioration test in which the charge and discharge cycle is carried out at 0° C. and by a high-temperature deterioration test in which the charge and discharge cycle is carried out at 60° C. That is, even in the case of using the product X of the capacity ΔQ′ between two points sandwiching an extreme point and the dQ/dV value at the extreme point, it is possible to accurately estimate the SOH of the secondary battery 10 in a variety of temperature ranges.

### EXAMPLES

### Example 1

As a secondary battery of Example 1, a lithium-ion secondary battery was produced. First, a positive electrode was prepared. A mixture of LiNi_{0.33}Mn_{0.33}Co_{0.33}O₂(NCM) and LiMn₂O₄(LMO) was prepared as a positive electrode active material, carbon black was prepared as a conductive material, and polyvinylidene fluoride (PVDF) was prepared as a binder. The weight ratio between NCM and LMO was set to 8:2. These were mixed in a solvent to produce a paint, and the paint was applied onto a positive electrode current collector made of an aluminum foil. The mass fractions of the positive electrode active material, the conductive material and the binder were set to 95:2:3. After the application, the solvent was removed. A positive electrode sheet in which the weight per unit area of the positive electrode active material was 10.0 mg/cm² was produced.

Next, a negative electrode was prepared. Graphite was prepared as a negative electrode active material, styrene-butadiene rubber (SBR) was prepared as a binder, and carboxymethyl cellulose (CMC) was prepared as a viscosity improver. These were dispersed in distilled water to produce a paint, and the paint was applied onto a negative electrode current collector made of a copper foil. The mass fractions of the negative electrode active material, the binder and the viscosity improver were set to 95:3:2. The applied paint was dried, and a negative electrode sheet in which the weight per unit area of the negative electrode active material was 10.0 mg/cm² was produced.

The positive electrode and the negative electrode, which were produced above, were laminated with a separator therebetween. As the separator, a laminate of polyethylene and polypropylene was used. An obtained power generation part was immersed in a prepared electrolytic solution, then, enclosed in an exterior body and then vacuum-sealed, thereby producing a lithium secondary battery for evaluation. As the electrolytic solution, an electrolytic solution obtained by dissolving 1.5 mol/L of lithium hexafluorophosphate (LiPF₆) in a solvent obtained by mixing ethylene carbonate (EC) and the same amount of dimethyl carbonate (DEC) was used.

While the charge and discharge cycle of the lithium secondary battery was repeated, the difference between the SOH actually measured at the 1000^{th} cycle and the estimated SOH was obtained. The charge and discharge cycle was carried out in a low-temperature environment (0° C.).

As the conditions for the first charging and discharging, the lithium-ion secondary battery was charged up to a final voltage of 4.2 V at a constant current corresponding to 0.2 C and then discharged to 3.0 V at a constant current corresponding to 0.2 C. 1 C represents a current value at which the reference capacity of a battery is discharged in one hour, and 0.2 C represents a current value of a fifth of 1 C. The actually measured SOH was obtained by dividing the capacity from fully charged to fully discharged in each cycle by the initial capacity from fully charged to fully discharged and multiplying the ratio by 100. The estimated SOH is a correction value obtained from the relational formula (1). In addition, the estimated SOH may be a correction value obtained using an inflection point on the Q-V curve. In the present example, an extreme point of dQ/dV was used in order to more clearly recognize the inflection point.

In Example 1, the maximum point P2 and the minimum point B3 were selected as the characteristic points for obtaining the capacity ΔQ (index α), and the maximum point P2 was used as the extreme point for obtaining the dQ/dV value (index β).

### Examples 2 to 5

In Examples 2 to 5, the selection of two extreme points for obtaining the capacity ΔQ and the extreme point for obtaining the dQ/dV value was different from Example 1. The other conditions were the same as in Example 1.

In Example 2, the maximum point P2 and the minimum point B3 were selected as the characteristic points for obtaining the capacity ΔQ, and the maximum point P3 was used as the extreme point for obtaining the dQ/dV value.

In Example 3, the maximum point P2 and the minimum point B3 were selected as the characteristic points for obtaining the capacity ΔQ, and the minimum point B3 was used as the extreme point for obtaining the dQ/dV value.

In Example 4, the maximum point P2 and the minimum point B2 were selected as the characteristic points for obtaining the capacity ΔQ, and the maximum point P3 was used as the extreme point for obtaining the dQ/dV value.

In Example 5, the maximum point P2 and the maximum point P3 were selected as the characteristic points for obtaining the capacity ΔQ, and the maximum point P3 was used as the extreme point for obtaining the dQ/dV value.

### Examples 6 to 8

Examples 6 to 8 are different from Example 1 in terms of the use of two points sandwiching a specific extreme point as the characteristic points for obtaining the capacity ΔQ′ (index α) and the selection of the extreme point for obtaining the dQ/dV value (index β). The other conditions were the same as in Example 1.

In Example 6, two points sandwiching the maximum point P2 were selected as the characteristic points, and the maximum point P3 was used as the extreme point for obtaining the dQ/dV value. The characteristic points are present at a height position at the central point in the vertical axis direction between the maximum point P2 and the minimum point B2.

In Example 7, two points sandwiching the maximum point P2 were selected as the characteristic points, and the maximum point P4 was used as the extreme point for obtaining the dQ/dV value. The characteristic points are present at a height position at the central point in the vertical axis direction between the maximum point P2 and the minimum point B2.

In Example 8, two points sandwiching the maximum point P3 were selected as the characteristic points, and the maximum point P4 was used as the extreme point for obtaining the dQ/dV value. The characteristic points are present at a height position at the central point in the vertical axis direction between the maximum point P3 and the minimum point B3.

### Comparative Example 1

In Comparative Example 1, correction was not carried out, and an estimated SOH was obtained from the integral current amount.

### Comparative Examples 2 to 4

In Comparative Examples 2 to 4, estimated SOH's were obtained using changes in the capacity ΔQ between two characteristic points (index α) due to deterioration. The two characteristic points were all extreme points.

In Comparative Example 2, the maximum point P2 and the minimum point B2 were selected as the characteristic points for obtaining the capacity ΔQ, and an estimated SOH was obtained using the capacity between them.

In Comparative Example 3, the maximum point P2 and the maximum point P3 were selected as the characteristic points for obtaining the capacity ΔQ, and an estimated SOH was obtained using the capacity between them.

In Comparative Example 4, the maximum point P2 and the minimum point B3 were selected as the characteristic points for obtaining the capacity ΔQ, and an estimated SOH was obtained using the capacity between them.

### Comparative Examples 5 and 6

In Comparative Examples 5 and 6, estimated SOH's were obtained using changes in the capacity ΔQ′ between two characteristic points (index α) due to deterioration. The two characteristic points were two points sandwiching a specific extreme point.

In Comparative Example 5, two points sandwiching the maximum point P2 were selected as the characteristic points, and an estimated SOH was obtained using the capacity ΔQ′ between them. The characteristic points are present at a height position at the central point in the vertical axis direction between the maximum point P2 and the minimum point B2.

In Comparative Example 6, two points sandwiching the maximum point P3 were selected as the characteristic points, and an estimated SOH was obtained using the capacity ΔQ′ between them. The characteristic points are present at a height position at the central point in the vertical axis direction between the maximum point P3 and the minimum point B3.

### Comparative Examples 7 to 10

In Comparative Examples 7 to 10, estimated SOH's were obtained using changes in the dQ/dV values at specific extreme points (index D) due to deterioration.

In Comparative Example 7, the maximum point P2 was selected as the extreme point for obtaining the dQ/dV value as the characteristic point, and an estimated SOH was obtained using a change in the dQ/dV value at the maximum point P2.

In Comparative Example 8, the maximum point P3 was selected as the extreme point for obtaining the dQ/dV value as the characteristic point, and an estimated SOH was obtained using a change in the dQ/dV value at the maximum point P3.

In Comparative Example 9, the minimum point B3 was selected as the extreme point for obtaining the dQ/dV value as the characteristic point, and an estimated SOH was obtained using a change in the dQ/dV value at the minimum point B3.

In Comparative Example 10, the maximum point P4 was selected as the extreme point for obtaining the dQ/dV value as the characteristic point, and an estimated SOH was obtained using a change in the dQ/dV value at the maximum point P4.

The results of the cycle tests of the secondary batteries of Examples 1 to 8 and Comparative Examples 1 to 10 are shown in Table 1.

TABLE 1

| | | | | | Difference between |
|---|---|---|---|---|---|
| | | | | Actually | controlled SOH |
| | | | Controlled | measured | and actually |
| | α | β | SOH | SOH | measured SOH |
| Comparative Example 1 | — | — | 47 | 75 | 28 |
| Comparative Example 2 | Capacity between P2 and B2 | — | 94 | 75 | 19 |
| Comparative Example 3 | Capacity between P2 and P3 | — | 55 | 75 | 20 |
| Comparative Example 4 | Capacity between P2 and B3 | — | 57 | 75 | 18 |
| Comparative Example 5 | P2 half-value width | — | 93 | 75 | 18 |
| Comparative Example 6 | P3 half-value width | — | 56 | 75 | 19 |
| Comparative Example 7 | — | P2 | 98 | 75 | 23 |
| Comparative Example 8 | — | P3 | 56 | 75 | 19 |
| Comparative Example 9 | — | B3 | 53 | 75 | 22 |
| Comparative Example 10 | — | P4 | 54 | 75 | 21 |
| Example 1 | Capacity between P2 and B3 | P2 | 67 | 75 | 8 |
| Example 2 | Capacity between P2 and B3 | P3 | 80 | 75 | 5 |
| Example 3 | Capacity between P2 and B3 | B3 | 73 | 75 | 2 |
| Example 4 | Capacity between P2 and B2 | P3 | 66 | 75 | 9 |
| Example 5 | Capacity between P2 and P3 | P3 | 82 | 75 | 7 |
| Example 6 | P2 half-value width | P3 | 69 | 75 | 6 |
| Example 7 | P2 half-value width | P4 | 77 | 75 | 2 |
| Example 8 | P3 half-value width | P4 | 84 | 75 | 9 |

As shown in Table 1, in Examples 1 to 8 where the product of two parameters was used, the errors between the actually measured SOH and the estimated SOH were smaller than those in Comparative Examples 1 to 10 where only any one of the parameters was used. This is considered to be because Examples 1 to 8 contain information on a change of the extreme point, the position of which changes due to deterioration, in the vertical axis (dQ/dV) direction and information on a change thereof in the horizontal axis (Q) direction.

### Example 9

In Example 9, the determination coefficient R² of the regression line of the relational formula (1) in each case was obtained by changing the combination of two extreme points for obtaining the capacity ΔQ and the extreme point for obtaining the dQ/dV value. In Example 9, the same secondary battery as in Example 1 was used. As the determination coefficient R² of the regression line becomes larger, the linear correlation becomes higher. Therefore, it can be said that, as the determination coefficient R² becomes larger, the error between the estimated SOH and the actually measured SOH becomes smaller. The results of Example 9 are summarized in Table 2.

TABLE 2

| | | β | | | | | | |
|---|---|---|---|---|---|---|---|---|
| | | B1 | B2 | B3 | P1 | P2 | P3 | P4 |
| α | P2-B1 | 0.884 | 0.779 | 0.808 | 0.705 | 0.747 | 0.789 | 0.845 |
| | B2-P2 | 0.790 | 0.724 | 0.741 | 0.725 | 0.731 | 0.746 | 0.841 |
| | P2-P1 | 0.917 | 0.793 | 0.912 | 0.637 | 0.783 | 0.853 | 0.659 |
| | B2-B1 | 0.835 | 0.763 | 0.773 | 0.734 | 0.739 | 0.768 | 0.889 |
| | P3-P2 | 0.812 | 0.672 | 0.754 | 0.766 | 0.763 | 0.805 | 0.804 |
| | B2-P1 | 0.882 | 0.830 | 0.824 | 0.732 | 0.756 | 0.802 | 0.926 |
| | B3-P2 | 0.914 | 0.822 | 0.843 | 0.757 | 0.756 | 0.826 | 0.864 |
| | P3-B1 | 0.863 | 0.748 | 0.797 | 0.768 | 0.762 | 0.818 | 0.865 |
| | P4-P2 | 0.947 | 0.832 | 0.937 | 0.702 | 0.784 | 0.882 | 0.632 |
| | P3-P1 | 0.899 | 0.804 | 0.843 | 0.759 | 0.774 | 0.850 | 0.863 |
| | B3-B1 | 0.922 | 0.842 | 0.848 | 0.750 | 0.755 | 0.824 | 0.881 |
| | B3-P1 | 0.947 | 0.890 | 0.888 | 0.734 | 0.766 | 0.848 | 0.848 |
| | P4-B1 | 0.961 | 0.893 | 0.925 | 0.713 | 0.777 | 0.867 | 0.725 |
| | P4-P1 | 0.955 | 0.864 | 0.947 | 0.687 | 0.785 | 0.881 | 0.655 |

(Verification Experiment)

A storage battery in which a SOH estimation process according to the present invention was combined into a control part (control device) was prepared. The storage battery (battery pack) was mainly composed of a battery management system including the control part and a safety mechanism and 10 lithium-ion secondary battery cells. The prepared storage battery was fully discharged at a 0.2 C rate at room temperature and then fully charged at a 0.2 C rate at room temperature, and the storage battery was put into an initial state of actual use. At the time of this charging, a Q-dQ/dV curve was acquired by obtaining a dQ/dV value at each voltage, and an SOH was recorded on software in the control part.

In order to intentionally cause the storage battery put into the initial state in the above-described process to deteriorate, a step of 100 cycles of charging and discharging was carried out. Here, the step of 100 cycles of charging and discharging has an evaluation step including at least the following elements.

1) A cycle in which the storage battery is fully discharged at a 0.5 C rate in a temperature environment of 45° C. and then fully charged at a 0.5 C rate is repeated 100 times.

2) After finally fully discharged (that is, fully discharged in the 100^{th} cycle), the storage battery is again fully charged at a 0.2 C rate at room temperature, and a dQ/dV value was obtained at each voltage during charging to acquire a Q-dQ/dV curve.

3) The Q-dQ/dV curve obtained after the step of 100 cycles of charging and discharging and the Q-dQ/dV curve in the initial state are compared.

4-1) In a case where a change in the maximum point shape is recognized, it is determined that the lithium-ion secondary battery in the storage battery has deteriorated, and the SOH value is recorded on the software of the control part.

4-2) In a case where no change in the maximum point shape is recognized, the operations 1) to 3) are repeated again.

In the present verification experiment, this step of 100 cycles of charging and discharging (the operations 1) to 4-2)) was repeated until three Q-dQ/dV curves different from the initial state and, similarly, three SOH values were obtained. Therefore, the Q-dQ/dV curve and the SOH value were obtained in each of three deterioration states (hereinafter, a first deterioration state, a second deterioration state and a third deterioration state) of the lithium-ion secondary battery.

The Q-dQ/dV curve in the first deterioration state, the Q-dQ/dV curve in the second deterioration state and the Q-dQ/dV curve in the third deterioration state were each output, and the products of the capacity between two characteristic points and the dQ/dV value at an extreme point were calculated. The obtained individual products and the SOH values output from the control part in the individual deterioration states were plotted along the X axis and the Y axis, respectively, and a favorable linear relationship represented by Y=AX+B was obtained. From this fact, it was possible to confirm the fact that, in the storage battery prepared in the present verification experiment, the correction of the SOH by the method of the present invention functions.

### REFERENCE SIGNS LIST

10 Secondary battery
20 Control device
21 dQ/dV calculation means
22 capacity-between-two-point calculation means
23 Intensity calculation means
24 Product calculation means
25 Correction means
100 Battery pack

1. A secondary battery control device,
wherein, on a Q-dQ/dV curve where dQ/dV that is a ratio of an amount of change in a capacity of a secondary battery to an amount of change in a voltage is indicated along a vertical axis and the capacity of the secondary battery is indicated along a horizontal axis, when a capacity between two characteristic points or two points mathematically equivalent thereto is represented by α,
a dQ/dV value at any extreme point of a plurality of extreme points plotted on the Q-dQ/dV curve or a point mathematically equivalent thereto is represented by β,
a product of the α and the β is represented by X, and
constants obtained in advance from a relationship between the X in a correction sample and a deterioration degree of the correction sample are represented by A and B,
a deterioration degree SOH of the secondary battery is corrected to SOH=AX+B . . . (1).

2. The secondary battery control device according to claim 1,
wherein both of the two characteristic points are any of the plurality of extreme points.

3. The secondary battery control device according to claim 1,
wherein the two characteristic points are two points sandwiching any of the plurality of extreme points.

4. The secondary battery control device according to claim 3,
wherein the extreme point sandwiched by the two characteristic points is a maximum point plotted in a voltage range of 3.6 V or higher and 3.8 V or lower on a V-dQ/dV curve where dQ/dV that is a ratio of an amount of change in a capacity of a secondary battery to an amount of change in a voltage is indicated along a vertical axis and the voltage of the secondary battery is indicated along a horizontal axis.

5. A secondary battery control device according to claim 1, comprising:
dQ/dV calculation means for calculating the dQ/dV;
capacity-between-two-point calculation means for selecting the two characteristic points on the Q-dQ/dV curve and obtaining the capacity between the two characteristic points;
intensity calculation means for selecting any extreme point of the plurality of extreme points on the Q-dQ/dV curve and obtaining a dQ/dV value at the extreme point;
calculation means for obtaining a product of the capacity between the two characteristic points and the dQ/dV value; and
correction means for correcting the deterioration degree of the secondary battery to a correction value based on a value obtained with the calculation means.

6. A battery pack comprising:
a secondary battery; and
the secondary battery control device according to claim 1.

7. The battery pack according to claim 6,
wherein the secondary battery contains a lithium nickel cobalt manganese composite oxide (NCM) and a lithium manganese oxide (LMO) in a positive electrode as active materials.

8. A secondary battery control method,
wherein, on a Q-dQ/dV curve where dQ/dV that is a ratio of an amount of change in a capacity of a secondary battery to an amount of change in a voltage is indicated along a vertical axis and the capacity of the secondary battery is indicated along a horizontal axis, when a capacity between two characteristic points or two points mathematically equivalent thereto is represented by α,
a dQ/dV value at any extreme point of a plurality of extreme points plotted on the Q-dQ/dV curve or a point mathematically equivalent thereto is represented by β,
a product of the α and the β is represented by X, and
constants obtained in advance from a relationship between the X in a correction sample and a deterioration degree of the correction sample are represented by A and B,
a deterioration degree SOH of the secondary battery is corrected to SOH=AX+B . . . (1).
